(19) United States
(12) Patent Application Publication
(10) Pub. No.: US 2011/0052792 A1
(43) Pub. Date: Mar. 3, 2011

(54) METHOD FOR PRINTING ELECTRONIC DEVICE USING MATCHING LOGIC AND METHOD FOR MANUFACTURING RFID TAG USING THE SAME

(76) Inventor: Kee-Hyun Shin, Seongnam-si (KR)

(21) Appl. No.: 12/941,977

(22) Filed: Nov. 8, 2010

(30) Foreign Application Priority Data
May 8, 2008 (KR) 10-2008-0043085
Aug. 4, 2008 (KR) PCT/KR2008/003727

(51) Int. Cl. C23C 16/52

(52) U.S. Cl. 427/8

(57) ABSTRACT

A method of producing an electronic device by a roll-to-roll printing process using matching logic, and a method of producing a RFID (radio frequency identification) tag. The method, which enables mass production of inexpensive printable electronic devices, includes: determining specs of the electronic device; determining matching conditions including substrate, ink and process conditions using impedance matching, chemical matching, process matching, geometry matching, mechanical matching, and time matching in view of the specs of the electronic device; printing using a roll-to-roll printing process under the matching conditions; examining a state of printed lines before and after drying; examining conductivity of the printed lines after curing and checking any breakage or short-circuit of the printed lines; testing final performance of the electronic device; and repeating the steps of determining matching conditions when any of the printed states, the conductivity, or the final performance is not within respective predetermined error tolerance ranges.

### CROSS-REFERENCE TO RELATED APPLICATIONS

This application claims priority to and is a continuation of a co-pending International Application No. PCT/KR2008/003727 filed on Aug. 4, 2008, which claimed priority to a patent application No. KR 10-2008-0043085, filed on May 8, 2008, in Korea, and hereby claims the benefit thereof.

### BACKGROUND OF THE INVENTION

The present invention relates to a method of printing electronic devices in a roll-to-roll process, using a matching logic, for mass production and reduction in production cost, and to a method of manufacturing a RFID (radio frequency identification) tag.

A continuous roll-to-roll printing process has been long known and used for printing conventional materials. Recently, it is receiving newer and greater attention in the art for its potential applicability in producing electronic devices because once implemented, it entails huge advantages, including the capability of mass-producing inexpensive electronic devices at reduced cost and time. As compared to this, the conventional batch-type production of electronic devices is disadvantageous because the production process is discontinuous and complicated due to the use of etching, resulting in low productivity and high production cost.

By contrast, a roll-to-roil process continuously produces a subject matter and directly prints the subject matter with ink containing metal nano-particles such as silver or nickel, therefore drastically increasing production rate. In order to apply a conventional printing technique used in a general printing medium to a roll-to-roll printing of an electronic device, however, there is a problem to be solved, that the printing precision must be greatly increased. The precision of a conventional printing process is about one hundred microns, which indicates a minimal error distinguishable with naked human eyes. However, many electronic devices require a printing precision of one to fifty microns, or less in some cases, depending on the field of application of the electronic devices.

Therefore, in order to achieve such a high printing precision in printing an electronic device using a roll-to-roll process, it is critically important to accurately determine and control various product parameters, and process conditions and parameters. More specifically, the conditions and parameters that are important to printing an electronic device by a roll-to-roll process, and therefore must be properly determined include: ink conditions such as ink viscosity, degree of mixing ink with solvent, the metal contents and metal particle size, water or lipid solubility; substrate conditions such as the type, width, and thickness of the substrate, the type of surface treatment needed, surface tension, surface roughness, light transmittance; process parameters such as substrate operation tension, operation rate, nip force; cell shapes, cell depth, cell width; drying conditions such as duration, temperature, distance, and means of drying; curing conditions such as duration, temperature, distance, and means of curing; and the type of a roll-to-roll process itself.

It has been known that many of these critical parameters and conditions are mutually and delicately dependent on one another and that the freedom of choice in determining the parameters and conditions is limited not only by the targeted specs and functionality of the electronic device to be produced, but also by physical or chemical compatibility among different parameters and conditions. Changing one parameter or condition may critically affect the choice of other parameters and conditions as well as overall productivity and performance of the electronic device. Therefore, to ensure the desired printing precision and enhance the productivity, it is important for these conditions and parameters to be determined in such a way to be adapted for the targeted spec of the electronic device, and at the same time, to match with one another physically, mechanically and chemically.

Although methods and techniques for printing electronic devices using a roll-to-roll process have been studied in the art for its potential huge benefits, up to date, there has not been developed any systematic, comprehensive, and integrated methodology to determine and control such various product and process parameters and conditions in producing an electrical device such as a RFID tag using a roll-to-roll printing process.

Therefore, there is a need in the art to devise a method of producing an electronic device using a roll-to-roll printing process that uses a logic, by which all critical product and process parameters and conditions are determined, controlled, and recalibrated in a single systematic, sequential, and integrated way so that the electronic device may be produced in a large scale by a smooth, fast and continuous roll-to-roll printing process with enhanced precision and lowered cost.

### SUMMARY OF THE INVENTION

In view of the afore-described needs in the art, one object of the present invention is to provide a method of producing electronic devices, such as a RFID (radio frequency identification) tag, solar cells, or signage, using a roll-to-roll printing process, which provides the capability of mass production and significant reduction of production cost and time.

Another object of the present invention is to provide a method for producing electronic devices, in which all major conditions and parameters critical to the roll-to-roll printing process are systematically, sequentially, comprehensively, and interactively determined and designed by an integrated logic such that they not only match the desired specs of the electronic device, but also match mutually.

Still another object of the present invention is to provide a method of producing an electronic device using a roll-to-roll printing process, in which the printing errors are repeatedly checked in production steps where the errors are frequently caused, and can be eliminated by conveniently and systematically recalibrating the conditions and parameters of the roll-to-roll printing process by devising a logic.

In order to accomplish the above objects, an aspect of the present invention provides a method of producing an electronic device by a roll-to-roll printing process, using matching logic, which includes: determining specs of the electronic device; determining matching conditions for a roll-to-roll printing process using impedance matching, chemical matching, process matching, geometry matching, mechanical matching, and time matching while considering the specs of the electronic device, the matching conditions including substrate, ink, process conditions, and the type of a roll-to-roll printing process of the electronic device; printing an electric circuit on a substrate using the roll-to-roll printing process under the matching conditions; examining a state of printed lines of the electric circuit before the electric circuit is dried; examining a state of printed lines of the electric circuit after the electric circuit is dried; examining conductivity of the electric circuit after the electronic circuit is cured; testing final performance of the electronic device in consideration of the specs of the electronic device; and repeating the steps of determining matching conditions and printing an electric circuit if any of the states of printed lines, the conductivity, and the final performance in is not within respective predetermined tolerance ranges of error.

The ink conditions may include the type of ink, viscosity, a degree of mixing with a solvent, metal content and metal particle size, and whether the ink is water-soluble or lipid-soluble, and the substrate conditions include the type, width, thickness of a web material to be used as a substrate, which are determined using the chemical matching in consideration of, in one aspect of the present invention, the surface tension and roughness of the substrate, the degree of adhesion interaction between the substrate and the ink, and drying and curing temperatures.

The impedance matching determines, in an aspect of the present invention, a thickness of a printed pattern and an interval between neighboring lines in the printed pattern, and the geometry matching determines a depth, a width and an inner shape of a recessed cell in a printing roll, and a coating material of the printing roll.

The process matching determines a type of a roll-to-roll printing process of the electronic device, which is selected from processes that may include, but is not limited to, gravure printing, flexographic printing, ink-jet printing, offset printing or hybrid printing. The mechanical matching determines, in an aspect of the present invention, an operation rate, an operation tension, a feed roll pressure, drying and curing conditions. The drying and curing conditions include the duration, temperature distance of drying and curing zones, and means for drying and curing.

In another aspect of the present invention, the mechanical matching may further determine the process conditions such as pressure of a riding roll for preventing inflow of air upon winding, tension of each span between consecutive printing rolls, width-to-length ration of the electronic device, taper tension, precision of a register control, and a cooling process.

Time matching determines, in an aspect of the present invention, change of a scheduling scheme and change of register and tension control methods.

In an aspect of the present invention, when examining a state of printed lines of the electric circuit, the thickness, thickness uniformity and any spreading of the printed lines are checked visually, and when examining conductivity of the electric circuit, any breakage or short-circuit of the electric circuit is checked.

Another aspect of the present invention provides a method of manufacturing an RFID tag using a matching logic, which includes: determining desired values of a bandwidth and a reading distance of a RFID tag; designing a shape and a thickness of an antenna adapted for the bandwidth and reading distance of the RFID tag; preparing ink for manufacturing the RFID tag; determining temperatures and distances, respectively, for a drying zone and a curing zone, considering curing conditions of the ink and an anticipated operation rate; determining a substrate; determining a type of a roll-to-roll printing process, a cell shape and a cell depth; determining process conditions; printing the antenna; examining the printed pattern of the antenna; drying the substrate with the printed antenna; examining the printed pattern of the antenna; curing the substrate with the printed antenna; examining conductivity of the cured antenna; bonding a RFID chip to the antenna; testing final performance of the RFID tag in view of the bandwidth and reading distance; and repeating the steps prior to printing the antenna when any of the printed pattern, the conductivity, and the final performance is not within respective predetermined tolerance ranges of error.

In an aspect of the invention, designing the shape and thickness of an antenna may be performed considering sensitivity of RFID driving performance to work surroundings and noise under which the RFID tag is to be used.

In an aspect of the invention, preparing ink may include determining a type, viscosity, and metal contents of ink. Determining the substrate may include determining the type, width, thickness of a web material to be used as a substrate in consideration of the surface tension and roughness of the substrate, the degree of adhesion interaction between the substrate and the ink, and drying and curing temperatures such that the substrate is not melted at a drying temperature and a curing temperature.

The determination of the type of a roll-to-roll printing process may be performed considering the type and viscosity of ink and the type of substrate, and the determination of a cell shape and a cell depth may be performed by considering the shape and thickness of the antenna. Also, the determination of process conditions may include, in an aspect of the invention, determining an operation rate, an operation tension, and a feed roll pressure.

In another aspect of the invention, the method of manufacturing an RFID tag using a matching logic may further include the step of determining change of a scheduling scheme and change of register and tension control methods.

In an aspect of the invention, the examination of the printed pattern of the antenna may be performed by visually checking the thickness, thickness uniformity and any spreading of the printed pattern, using a microscope. Also, the examination of conductivity of the cured antenna may include checking any breakage or short-circuit of the printed pattern.

In accordance of the present invention, one of the advantages provided by the matching logic in the present invention is the capability of mass production of electrical devices and significant reduction of production cost and time, which results from effective, comprehensive and systematic designing of the roll-to-roll printing process by determining critical process conditions and production parameters through the matching logic.

Another advantage of the present invention is the capability of efficiently and promptly controlling quality of the electronic devices produced by repeatedly checking the printing errors at steps known as the frequent sources of error and eliminating them by systematically recalibrating the conditions and parameters of the roll-to-roll printing process through the matching logic.

A further advantage of the present invention is to provide a method of manufacturing a RFID tag using a roll-to-roll printing process through the matching logic.

### BRIEF DESCRIPTION OF THE DRAWINGS

FIG. 1 is part of a flowchart schematically illustrating a process of printing an electronic device using a matching logic according to the present invention;

FIG. 2 is part of a flowchart, continuing from the flow chart in FIG. 1, schematically illustrating a process of printing an electronic device through a matching logic according to the present invention; and

FIG. 3 is a flowchart schematically illustrating a process of manufacturing an RFID (radio frequency identification) tag using a roll-to-roll printing process using a matching logic according to the present invention.

### DETAILED DESCRIPTION OF THE INVENTION

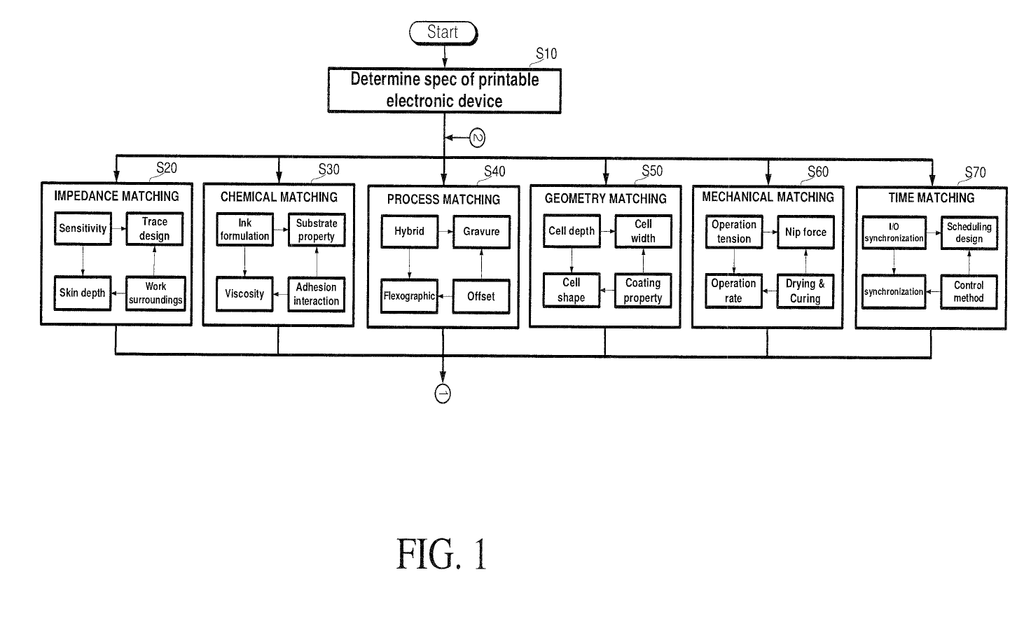

The drawings, FIGS. 1-3, to be described herein are shown for purposes of illustrating only certain embodiments of the present invention, and not for any purpose of limiting the invention. Further, the terms and words used in the present specification and claims should not be interpreted as being limited to typical meanings or dictionary definitions, but should be interpreted as having meanings and concepts relevant to the technical scope of the present invention.

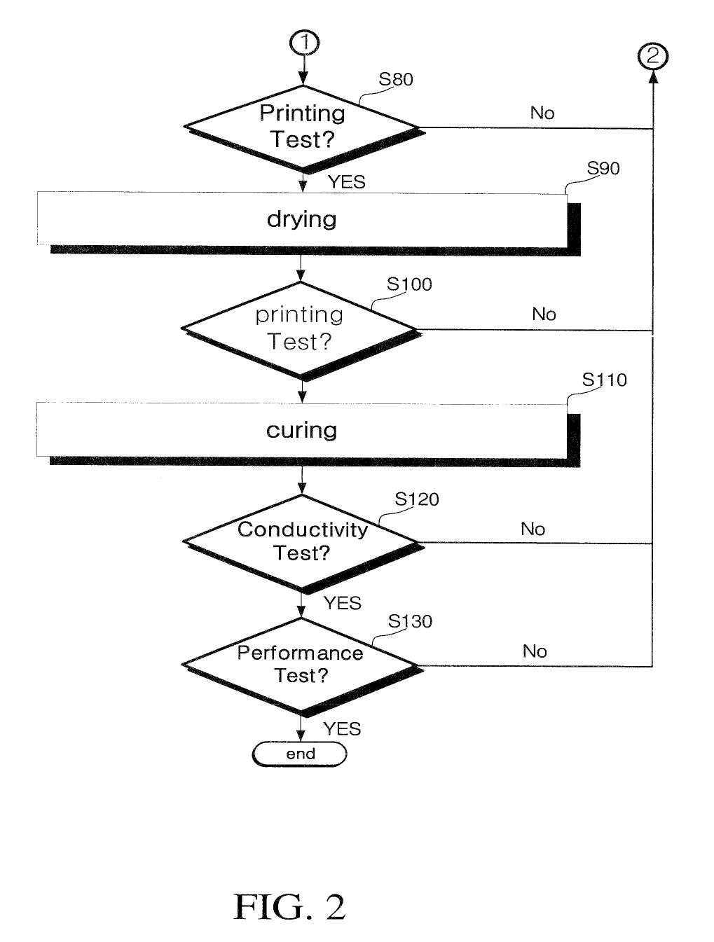

FIGS. 1 and 2 show, as combined, a flowchart illustrating a method, in accordance with the present invention, of producing an electronic device using a roll-to-roll printing process, by using matching logic. Before utilizing the method of the present invention, the type of a particular electronic device to be printed by a roll-to-roll process using the method in the present invention is chosen. The electronic device may be chosen from any electronic device that is printable, which may include, but is not limited to, a RFID (radio frequency identification) tag, a solar cell, a signage, or other electronic devices compatible for production by utilizing a roll-to-roll process.

Referring now to FIG. 1, the first step of the method in the present invention is to determine the specs of the chosen electric device to be printed. (S10) Such specs could include target values of the conductivity of the printed electric circuits, other electric properties or functions specific to the selected electronic device, and their respective ranges of tolerance of error. The specs are determined in consideration of the current level of printing technology and its accuracy, and vary depending on the specific type of the electronic device selected. For instance, if the subject matter is a RFID tag, the specs to be determined in this step may include the conductivity, the bandwidth and reading distance of the RFID tag, and respective ranges of tolerance of error.

The next steps in the present invention are to determine, by applying the matching logic, a variety of matching conditions that are needed to be determined for producing the target electric device using a roll-to-roll printing. In the matching logic, such conditions are determined so as to be adapted for the specs of the target electronic device that are determined in the first step (S10) and also in such a way to be technically, chemically, and mechanically commensurate and compatible with other relevant matching conditions determined in the matching logic.

The types of matching under the matching logic to determine such matching conditions may include impedance matching, chemical matching, process matching, geometry matching, mechanical matching and time matching (S20-S70). Specifically, the matching conditions to be determined in each type of matching are as follows.

The matching conditions to be determined during the impedance matching (S20) may include, in an embodiment of the present invention, the thickness of a printed pattern (skin depth) and intervals between neighboring lines in the printed pattern (trace design). These conditions are determined in consideration of the specs of the target electronic device in S10. In another embodiment of the present invention, the conditions to be determined during the impedance matching may include the sensitivity of the electronic device to be printed, which may be determined in consideration of the surroundings in which the electronic device is worked or used. For instance, if the electronic device is a RFID tag, the sensitivity of its driving performance is determined in view of expected work surroundings and noise level.

The matching conditions to be determined during the chemical matching (S30) include the ink conditions and substrate conditions. The ink conditions may include the type of ink, the composition of the ink such as the metal content, the metal particle size, the properties of ink such as the viscosity, which may be used to determine the degree of mixing of ink with a solvent, the amount of ink to be transferred to a substrate, the behavior of the ink transferred from a printing pattern on a roll upon transfer of the ink, and whether the ink is water-soluble or lipid-soluble.

In the process matching, the type of a particular roll-to-roll printing process is determined (S40). Examples of a roll-to-roll printing process for use with the present invention may include gravure printing, flexographic printing, offset printing and hybrid printing, each of which requires printing rolls, and ink-jet printing which does not. In determining the particular type of the printing process, the previously determined matching conditions, in particular, the cell width on the printing roll determined in the impedance matching and ink viscosity determined in the impedance matching are primarily considered.

After the type of roll-to-roll printing process is determined, the geometry matching (S50) determines, if the determined printing process uses printing rolls: the shape (cell shape), depth (cell depth) and width (cell width) of a recessed cell in the printing rolls. These matching conditions are closely dependent upon the conditions determined in the impedance matching such as the shape, thickness (skin depth), and width of the printed pattern as well as the intervals between neighboring lines in the printed pattern (trace design), and also correlated with the amount of ink to be transferred. The shell shape in the printing rolls may be a quadrangular shape, a pyramidal shape or a tri-helical shape. The geometry matching may further determine the coating property of a printing roll, for instance, the kind of a coating material such as nickel, chromium, etc. If the target electronic device is a RFID tag, the size and position of the RFID chip to be bonded after the antenna is printed must be also considered in determining the above-mentioned conditions for a recessed cell on printing rolls.

After the particular type of roll-to-roll printing process is determined, the various specs of the roll-to-roll printing process are determined during the mechanical matching (S60) in consideration of the matching conditions determined in the previous steps of the process in the present invention, S20-S50. The matching conditions to be determined during this matching may include, in an embodiment of the present invention: operation tension, which is the tension applied to the subject matter printed upon the substrate while in transit; nip force, which is the pressure between an impression or nip roll and a printing or feed roll upon printing; the pressure of a riding roll for preventing inflow of air upon winding; operation rate, which is transport velocity of the substrate, and is correlated with the rate and amount of transfer of ink; and drying and curing conditions.

The drying conditions may include the duration, temperature and distance of a drying zone, and means for drying such as hot air or other kind of gas. Similarly, the curing conditions may include the duration, temperature and distance of a curing zone, and the means for curing. For curing, which is to solidify and protect the printed pattern that is transferred onto a substrate in a liquid or gel state, commonly used curing materials are infrared light, ultra-violet light or electron beams. In determining the drying and curing conditions, the operation rate is considered. In determining the curing conditions, the curing condition of ink is also considered.

In an embodiment of the present invention, the mechanical matching may further determine additional specs of the particular roll-to-roll printing process that may include: the tension of each span between consecutive printing rolls before and after printing; the ratio of width to the length (the interval between rolls) of the substrate; taper tension applied to the printed subject matte at the stage of winding it around a winding roll; the precision of a register control specific to the chosen roll-to-roll printing process; and a cooling process.

The substrate conditions, part of the matching conditions determined during the chemical matching (S30), may include the type, width and thickness of a web material to be used as the substrate. In such determination, the ink conditions that have been previously determined are considered such that the substrate may be chemically adapted for and compatible with the determined type of ink utilized in the process. Particularly, the substrate properties such as the surface tension and roughness and the degree of adhesion interaction between the substrate and the ink to be transferred thereon are considered. Also, the drying and curing temperatures, which are determined in the mechanical matching (S60), are considered such that the substrate is not melted at the drying and curing temperatures.

The matching conditions to be determined during the time matching (S70) may include, in an embodiment of the present invention: change of any scheduling scheme in a real time operating system (OS) such as RM (rate monotonic), EDF (earliest deadline first), LDF (latest deadline first) or etc.; change of any register or tension control method such as PID (proportional integral derivative) control, feed-forward control, MIMO (multi input multi output) control; and change of input/output synchronization.

Now referring to FIG. 2, after the subject matter, an electric circuit, is printed with the ink through the roll-to-roll process, the state of printing of the electric circuit is visually examined by, preferably, a microscope (S80). In other embodiments, however, the examination may be performed by utilizing sensors. Specifically, the line thickness, thickness uniformity, and any spreading of printed lines may be checked. If the printed state is not within the tolerance range of error predetermined in S10, as indicated by the ‘NO’ in S80 in FIG. 2, the procedure returns to the prior steps of the present invention, S20 through S70, where matching conditions are re-determined and readjusted. But, if the printed state is good, as indicated by the ‘YES’ in S80 in FIG. 2, the procedure proceeds to the step of drying the printed subject matter (S90), in which the printed subject matter are dried under the drying conditions and means previously determined in S60.

In an embodiment of the present invention, the printed subject matter may be re-examined (S100), for example, visually by a microscope or by using sensors, after drying the subject matter for any error in the printed lines that may have occurred during the drying step due to, for example, hot air or gas. Again, the line thickness, thickness uniformity, and any spreading of printed lines may be checked. If an error in the printed lines is greater than the predetermined tolerance range of error, as indicated by the ‘NO’ in S100 in FIG. 2, the procedure returns to the prior steps, S20 through S90, where matching conditions, especially the drying conditions, are re-determined and readjusted. But, if the printed state is good, as indicated by the ‘YES’ in S100 in FIG. 2, the procedure proceeds to the next step of curing the printed subject matter (S110).

Next, the dried subject matter is cured (S110) under the curing conditions by using the curing materials previously determined in S60. During curing, the printed ink is metalized and metal particles are melted and interconnected.

After curing the subject matter, conductivity of the cured subject matter, the electric circuit, is examined (S120) to spot any physical breakage of printed lines or short-circuit of the printed lines. If the value of conductivity is not within the predetermined tolerance error range from its target value, as indicated by the ‘NO’ in S120 in FIG. 2, which may be one of the previously determined specs of the electronic device in S10, the procedure again returns to the prior steps, S20 through S110. But, if the value of conductivity falls within the predetermined range of error tolerance, as indicated by the ‘YES’ in S120 in FIG. 2, the procedure proceeds to the next step (S130), where performance of a final product is tested. Here, whether the electric properties or functions specific to the printed electronic device measure up to the target values preset in S10 in determining the specs of the electronic device are tested. For example, if the target electronic device is a RFID tag, what is tested in this step may be the receiving distance and reading rate of the RFID tag.

Again, if the performance test result of the final product is not satisfactory, that is, the tested values of the electric properties or functions specific to the printed electronic device are greater than the respective ranges of error tolerance predetermined in S10 as indicated by the ‘NO’ in S130 in FIG. 2, the procedure once again returns to the prior steps S20 through S120. If the final product performance is satisfactory enough, as indicated by the ‘YES’ in S130 in FIG. 2, the production of an electronic device via a roll-to-roll printing process, by using a matching logic in the present invention, is completed.

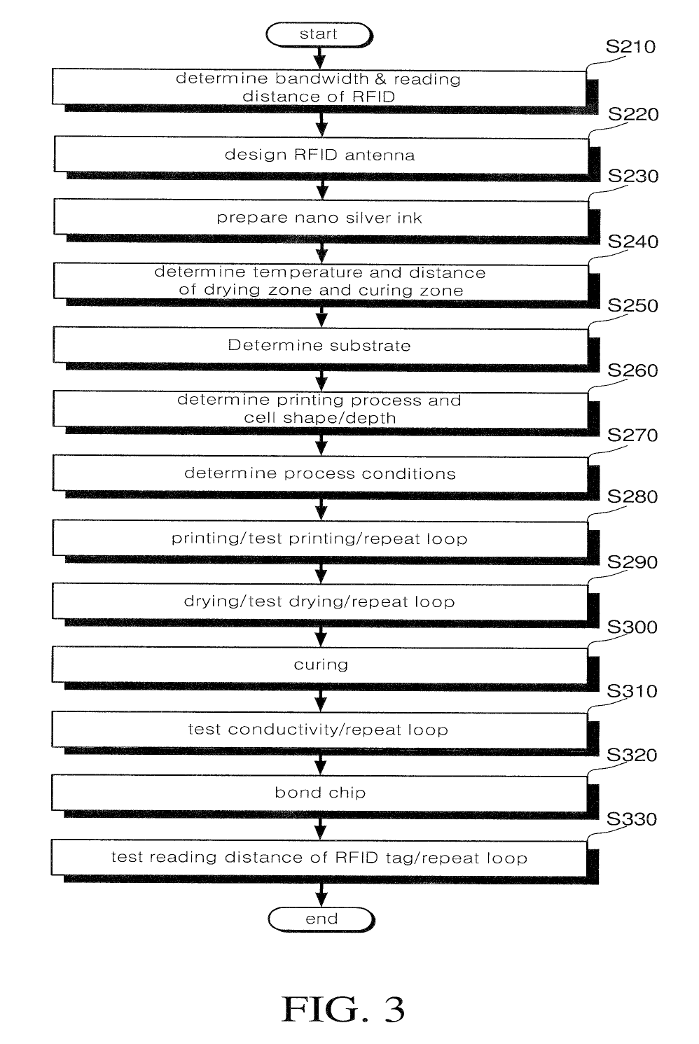

FIG. 3 is a flowchart showing a process of producing a RFID (radio frequency identification) tag using a roll-to-roll printing process using matching logic according to one embodiment of the present invention.

First, target values of the bandwidth and reading distance of the RFID tag to be manufactured, and their respective ranges of tolerance of error are determined (S210). For example, in one embodiment, the bandwidth of the RFID tag may be 900 MHz and the reading distance may be six meters or more.

Next, a RFID antenna is designed using an impedance matching (S220) such that it may be adapted for the bandwidth and the reading distance of the RFID tag determined in the previous step. In this matching, for example, the shape and thickness of the antenna are determined. In such determination, the sensitivity of the driving performance of the RFID tag to work surroundings and noise under which the RFID tag is to be used may be considered.

In the next stage, as part of the chemical matching, the type of ink to be used for manufacturing the RFID tag is determined (S230), together with its properties such as the metal contents in the ink and the viscosity of the ink. In one embodiment of the present invention, the ink may contain silver nano-particles.

Next, the curing and drying conditions, part of the mechanical matching conditions, are determined in (S240). The curing conditions may include the curing temperature and the curing distance, which the subject matter will travel during a curing procedure in the curing zone. Similarly, the drying conditions may include the drying temperature and the drying distance. In determining those conditions, the curing conditions of the ink and the anticipated operation rate may be considered. In one embodiment of the present invention, the curing temperature is 150 degree Celsius, the curing time is 180 seconds, the operation rate is 20 meters/min, and the curing distance is 60 meters.

In the next stage, another part of the chemical matching, the type of a substrate is determined (S250). The type of the substrate is chosen such that the substrate will not melt at the previously determined drying and curing temperatures during the drying and curing procedures after the antenna is printed on the substrate. Also, it should be taken account that the substrate may be subjected to a surface roughness treatment or a surface coating treatment depending on the adhesion interaction between the substrate and the previously selected ink. In one embodiment of the present invention, the substrate may be a thermosetting PET (polyethylene terephthalate).

Next, the type of a roll-to-roll printing process is determined, in process matching, so as to be adapted for the type and viscosity of ink and substrate selected (S260). In one embodiment of the present invention that uses ink containing silver nano-particles and thermosetting PET as the substrate, a gravure printing is chosen for printing the RFID tag. After then, the cell shape and depth on printing rolls is determined using geometry matching by considering the shape and thickness of the antenna to be printed, which have been previously determined during impedance matching. In the embodiment of the present invention that uses a gravure printing, the cell has a square shape with the cell depth of 39 micrometers.

After the type of a roll-to-roll printing process is determined, the specs for the roll-to-roll printing, or the process conditions, are determined using mechanical matching (S270). The process conditions may include an operation tension, an operation rate, and a feed roll pressure or nip force. In one embodiment of the present invention, the operation tension is chosen to be 60 Newtons, the operation rate is 20 meters/min, and the feed roll pressure is 20 Newtons. In one embodiment, the process conditions may further include pressure of a riding roll for preventing inflow of air upon winding, tension of each span between consecutive printing rolls, width-to-length ratio of the substrate, taper tension, precision of a register control, and a cooling process.

After the printing is performed by the particular roll-to-roll printing process and process conditions determined in steps (S260) and (S270), the quality of the printed pattern is visually examined using a microscope (S280). In particular, the line thickness, uniformity in thickness, and any spreading of printed lines may be checked. If the printing quality is poor, that is, if the error measured goes beyond the predetermined range of tolerance of error, the procedure returns to the prior steps, (S230) through (S270), where the matching conditions previously determined are re-determined and readjusted.

Next, the subject matter having the printed pattern is dried under the previously determined drying conditions, and the dried subject matter is checked by using a microscope (S290) for any error in the printed lines that might have been generated due to hot air used for the drying. In particular, the line thickness, thickness uniformity, and any spreading of printed lines may be checked again. If the printing quality is beyond the predetermined tolerance of error range, the procedure returns to the prior steps and repeats the steps of (S230) through (S280).

Next, the dried subject matter is cured (S300) at the curing temperature for the curing time determined at the prior step of (S240).

After the curing of the subject matter having the printed pattern, the electrical conductivity of the cured printed pattern is tested and any physical breakage or short circuit thereof is examined (S310). If the value of conductivity is not within the predetermined error tolerance range for conductivity, the procedure again returns to the prior steps, (S230) through (S300).

Next, a RFID chip is bonded to the printed antenna (S320). Lastly, the bandwidth and reading distance are checked as the indicator of the degree of performance of the final product, the RFID tag (S330). If the values of the bandwidth and reading distance are not within the predetermined respective error tolerance ranges, the procedure again returns to the prior steps, (S230) through (S320).

While particular forms of the inventions have been illustrated and described, it will be apparent to those skilled in the art that various modifications, additions and substitutions can be made without departing from the inventive concept. References to use of the invention with a specific materials or procedures in describing and illustrating the invention herein are by way of example only, and the described embodiments are to be considered in all respects only as illustrative and not restrictive. The present invention may be embodied in other specific forms without departing from its spirit or essential characteristics. Accordingly, it should be understood that the scope of the invention is defined by the accompanying claims only.

We claim:

1. A method of producing an electronic device by a roll-to-roll printing process, using matching logic, the method comprising the steps of:
(a) determining specs of the electronic device;
(b) determining matching conditions for a roll-to-roll printing process using impedance matching, chemical matching, process matching, geometry matching, mechanical matching, and time matching while considering the specs of the electronic device, the matching conditions including substrate conditions, ink conditions, process conditions, and the type of a roll-to-roll printing process of the electronic device;
(c) printing an electric circuit on a substrate by the roll-to-roll printing process under the matching conditions;
(d) examining a state of printed lines of the electric circuit before the electric circuit is dried;
(e) examining a state of printed lines of the electric circuit after the electric circuit is dried;
(f) examining conductivity of the electric circuit after the electronic circuit is cured;
(g) testing final performance of the electronic device in consideration of the specs of the electronic device; and
(h) repeating steps (b) and (c) if any of the states of printed lines in steps (d) and (e), the conductivity in step (f), and the final performance in step (g) is not within respective predetermined tolerance ranges of error.

2. The method of claim 1, wherein the ink conditions include the type of ink, viscosity, a degree of mixing with a solvent, metal content and metal particle size, and whether the ink is water-soluble or lipid-soluble.

3. The method of claim 1, wherein the substrate conditions include the type, width, thickness of a web material to be used as a substrate.

4. The method of claim 3, wherein the substrate conditions are determined using the chemical matching in consideration of the surface tension and roughness of the substrate, the degree of adhesion interaction between the substrate and the ink, and drying and curing temperatures.

5. The method of claim 1, wherein the matching conditions determined using the impedance matching include a thickness of a printed pattern and an interval between neighboring lines in the printed pattern.

6. The method of claim 1, wherein the matching conditions determined using the geometry matching include a depth, a width and an inner shape of a cell in a printing roll, and a coating material of the printing roll.

7. The method of claim 1, wherein the matching conditions determined using the process matching include a type of a roll-to-roll printing process of the electronic device that is selected from the group consisting of gravure printing, flexographic printing, ink-jet printing, offset printing or hybrid printing.

8. The method of claim 1, wherein the process conditions include an operation rate, an operation tension, a feed roll pressure, drying and curing conditions, and are determined by using the mechanical matching.

9. The method of claim 8, wherein the drying conditions include the duration, temperature and distance of a drying zone and means for drying, and the curing conditions include the duration, temperature and distance of a curing zone and means for curing.

10. The method of claim 8, wherein the process conditions further include pressure of a riding roll for preventing inflow of air upon winding, tension of each span between consecutive printing rolls, width-to-length ration of the substrate, taper tension, precision of a register control, and a cooling process.

11. The method of claim 1, wherein the matching conditions determined using the time matching include change of a scheduling scheme and change of register and tension control methods.

12. The method of claim 1, wherein examining a state of printed lines of the electric circuit in (d) and (e) includes checking thickness, thickness uniformity and any spreading of the printed lines.

13. The method of claim 1, wherein examining conductivity of the electric circuit includes checking any breakage or short-circuit of the electric circuit.

14. The method of claim 1, wherein the electronic device is selected from the group consisting of a RFID tag, a solar cell, and signage.

15. A method of producing a RFID (radio frequency identification) tag by a roll-to-roll printing process, using matching logic, the method comprising the steps of:
(a) determining desired values of a bandwidth and a reading distance of a RFID tag;
(b) designing a shape and a thickness of an antenna adapted for the bandwidth and reading distance of the RFID tag;
(c) preparing ink for manufacturing the RFID tag;
(d) determining temperatures and distances, respectively, for a drying zone and a curing zone, considering curing conditions of the ink and an anticipated operation rate;
(e) determining a substrate;
(f) determining a type of a roll-to-roll printing process, a cell shape and a cell depth;
(g) determining process conditions;
(h) printing the antenna;
(i) examining the printed pattern of the antenna;
(j) drying the substrate with the printed antenna;
(k) examining the printed pattern of the antenna;
(l) curing the substrate with the printed antenna;
(m) examining conductivity of the cured antenna;
(n) bonding a RFID chip to the antenna;
(o) testing final performance of the RFID tag in view of the bandwidth and reading distance; and
(p) repeating steps (c) to (h) when any of the printed pattern in steps (i) and
(k), the conductivity in step (m), and the final performance in step (o) is not within respective predetermined tolerance ranges of error.

16. The method of claim 15, wherein designing a shape and a thickness of an antenna in step (b) includes considering sensitivity of RFID driving performance to work surroundings and noise under which the RFID tag is to be used.

17. The method of claim 15, wherein preparing ink in step (c) includes determining a type, viscosity, and metal contents of ink.

18. The method of claim 15, wherein determining a substrate in step (e) includes determining the type, width, thickness of a web material to be used as a substrate.

19. The method of claim 18, wherein determining a substrate in step (e) further includes considering the surface tension and roughness of the substrate, the degree of adhesion interaction between the substrate and the ink, and drying and curing temperatures such that the substrate is not melted at a drying temperature and a curing temperature.

20. The method of claim 15, wherein determining a type of a roll-to-roll printing process in step (f) includes considering the type and viscosity of ink and the type of substrate.

21. The method of claim 15, wherein determining a cell shape and a cell depth in step (f) includes considering the shape and thickness of the antenna.

22. The method of claim 15, wherein determining process conditions in step (g) includes determining an operation rate, an operation tension, and a feed roll pressure.

23. The method of claim 22, wherein determining process conditions in step (g) further includes determining: pressure of a riding roll for preventing inflow of air upon winding, tension of each span between consecutive printing rolls, width-to-length ration of the substrate, taper tension, precision of a register control, and a cooling process.

24. The method of claim 15, further comprising the step of determining change of a scheduling scheme and change of register and tension control methods.

25. The method of claim 15, wherein examining the printed pattern of the antenna in steps (i) and (k) includes checking thickness, thickness uniformity and any spreading of the printed pattern.

26. The method of claim 25, wherein examining the printed pattern of the antenna in steps (i) and (k) includes visually checking the printed pattern using a microscope.

27. The method of claim 15, wherein examining conductivity of the cured antenna in step (m) includes checking any breakage or short-circuit of the printed pattern.
